(19) United States
(12) Patent Application Publication
(10) Pub. No.: US 2005/0001660 A1
(43) Pub. Date: Jan. 6, 2005

(54) Power-on reset circuit

(76) Inventor: Amit Roy, Sahibabad (IN)

Correspondence Address: HOGAN & HARTSON LLP, ONE TABOR CENTER, SUITE 1500, 1200 SEVENTEENTH ST, DENVER, CO, 80202, US

(21) Appl. No.: 10/874,815

(22) Filed: Jun. 22, 2004

(30) Foreign Application Priority Data
Jun. 26, 2003 (IN) 842/DEL/2003

(51) Int. Cl. H03L 7/00

(52) U.S. Cl. 327/143

(57) ABSTRACT

An improved Power-On Reset (POR) circuit providing enhanced reliability and automatic power-down capability. The POR circuit includes a supply voltage sensing circuit, a delay element connected to the output of the supply voltage sensing circuit, and a switch that activates the output POR signal when the output of the delay element indicates a reduced supply voltage. The switch further acts to deactivate the POR output and provide feedback to reduce current through the supply voltage sensing circuit once the supply voltage is normal.

### FIELD OF THE INVENTION

This invention relates to the field of Power-on Reset (POR) circuits. In particular, it relates to an improved Power-On Reset (POR) circuit that self powers down after performing its function.

### BACKGROUND OF THE INVENTION

During power up, it is required that electronic circuits should be in a known state to ensure proper functionality. This initialization is generally provided by Power-On Reset (POR) circuitry. There are numerous POR solutions available. Most of them consume some finite current from the power supply even after the completion of the reset process. It is observed that in certain applications, e.g., low power applications, this unnecessary power drain is unacceptable. The power consumed by these blocks can be saved by either switching off the clock to these blocks or by switching off its biasing voltage.

In existing low-power implementations of POR circuits, the biasing voltage to the POR circuitry is stopped after the initialization of the system. Generally, the disabling signal is a digital signal which is either a logic ‘1’ or a logic ‘0’. However this signal is itself in an undefined state on power on, resulting in unreliable operation.

FIG. 1 shows one example of a conventional POR circuit. Resistor R is connected at one end to the positive supply VDD and at the other end to capacitor C. The opposite end of capacitor C is connected to supply ground VSS. The junction of the resistor R and capacitor C, i.e., node ‘Vin’, connects to the input of inverter IV. The output of inverter IV provides the POR output.

FIG. 2 shows the operation of the POR circuit of FIG. 1. As the power supply voltage VDD rises, the voltage at the node Vin also rises as capacitor C charges through resistor R. Vin rises along a curve which is defined by the time constant determined by the values of R and C.

Initially, the voltage at node Vin is below the threshold voltage of inverter IV, and correspondingly, the output of the inverter IV is ‘HIGH’ providing an active POR signal. Vin rises along a curve which is defined by the time constant of the resistor R and capacitor C.

When the voltage at node Vin crosses the threshold voltage of the inverter IV, the output of the inverter IV goes ‘low’ causing the POR signal to be de-asserted. Generally, the time constant of the RC network has to be kept fairly high compared to the power supply rise time, resulting in large values of R and C. Though the POR circuit of FIG. 1 as such does not consume any power after the POR is de-asserted, it is impractical to fabricate the POR circuit of FIG. 1 as an integrated circuit as the R and C require a very large area.

FIG. 3 describes another POR circuit that is used quite frequently. PMOS transistor P1 is arranged in series with NMOS transistor N1. The gate Gp1 of PMOS transistor P1 is connected to ground, while its source Sp1 is connected to power supply terminal VDD and its drain Dp1 is connected to node V1. Gate Gn1 and drain Dn1 of NMOS transistor N1 are shorted together and connected to node V1, while the source Sn1 is connected to the supply ground VSS. The gate GP2 of PMOS transistor P2 is connected to node V1, while its drain Dp2 is connected to output POR and its source Sp2 is connected to power supply terminal VDD. NMOS transistor N2 has its gate Gn2 connected to node V1, drain Dn2 connected to the output POR, and source Sn2 connected to the power supply ground terminal VSS. When the power supply VDD is applied, node V1 follows the VDD as long as it is less than the threshold voltage of N1, which remains off. As soon as the power supply VDD reaches the switching threshold, Vtn, of N1 and N2 (Vtn1=Vtn2), both N1 (working as a diode) and N2 turn on and V2 goes to zero causing POR to be asserted. Further rise of power supply VDD will cause node V1 to rise because the difference in the current sunk by N1 and the current sourced by P1 will charge up the stray capacitance causing V1 to rise. As soon as V1 reaches the switching threshold, Vtp2, V2 goes high and POR is de-asserted.

FIG. 4 depicts the behavior of the POR circuit shown in FIG. 3. The threshold voltage of transistor P2 is:
Vtp2=V1 (voltage across the diode)+Vtn
This circuit suffers from the drawback that it consumes power from the power supply even in the idle state and is therefore not suitable for low-power applications.

### SUMMARY OF THE INVENTION

The object of the invention is to obviate the above drawbacks and provide a Power-On Reset (POR) circuit that operates reliably at the time of application of power and that powers itself down once the required reset pulse for the initialization of the remaining circuitry has been generated.

To achieve this objective, the present invention provides an improved POR circuit that monitors the power supply voltage and employs a controlled feedback mechanism to ensure a proper reset pulse output even under the condition of a varying power supply voltage and that powers itself down once the required power supply voltage has been achieved.

Accordingly, one embodiment of the invention comprises an improved POR circuit providing enhanced reliability and automatic power-down capability. The POR circuit includes the following:
a supply voltage sensing circuit,
a delay element connected to the output of the supply voltage sensing circuit, and
a controlled switch that activates the output POR signal when the output of the delay element indicates a reduced supply voltage and deactivates the POR output and provides controlled feedback to reduce current through the supply voltage sensing circuit once the supply voltage is normal.

In some embodiments, the supply voltage sensing circuit is a constant current source connected to a current sink whose output is controlled by the feedback from the POR output. The delay element is a capacitor charged by the current difference between the constant current source and current sink. The controlled switch disables the current sink when the supply voltage is normal. The constant current source is connected to the current sink through an isolating switch.

### BRIEF DESCRIPTION OF THE DRAWINGS

The invention will now be described with reference to the accompanying drawings:

FIG. 1 shows a conventional POR circuit.

FIG. 2 shows the operation of the conventional circuit in FIG. 1.

FIG. 3 shows another conventional POR circuit.

FIG. 4 shows the behavior of the conventional circuit in FIG. 3.

FIG. 5 shows an improved POR circuit according to the present invention.

FIGS. 6 and 7 show the operation of the circuit in FIG. 5 according to the present invention.

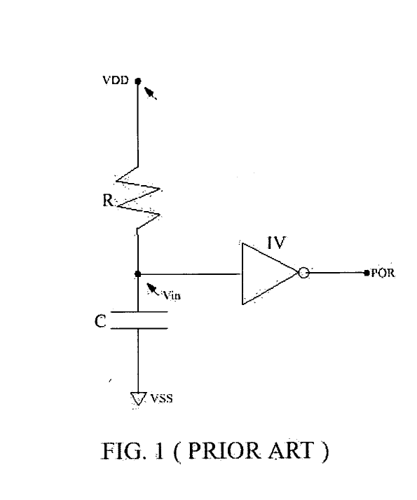

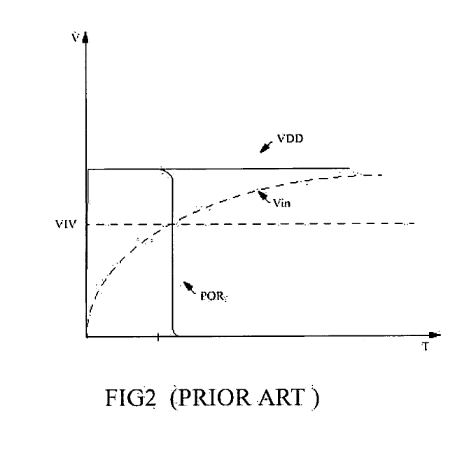

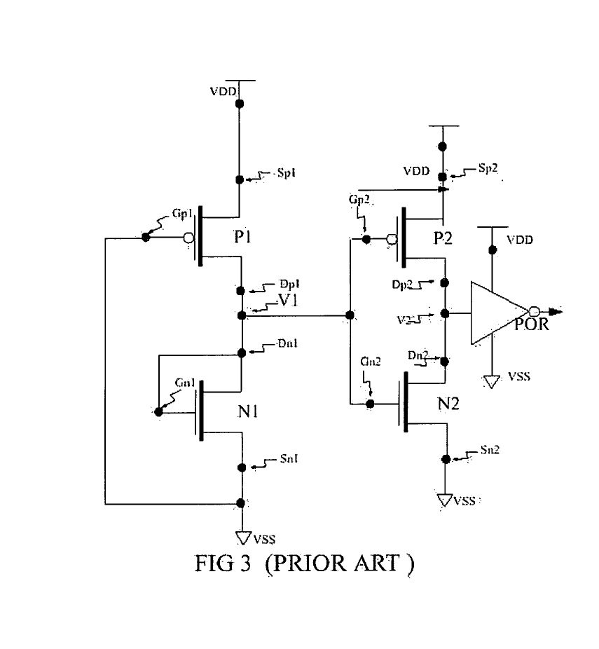

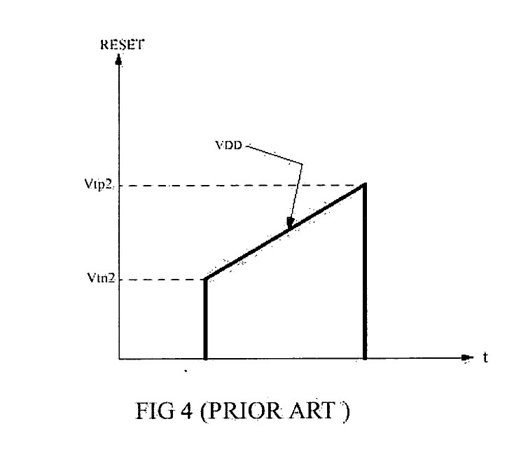

### DETAILED DESCRIPTION

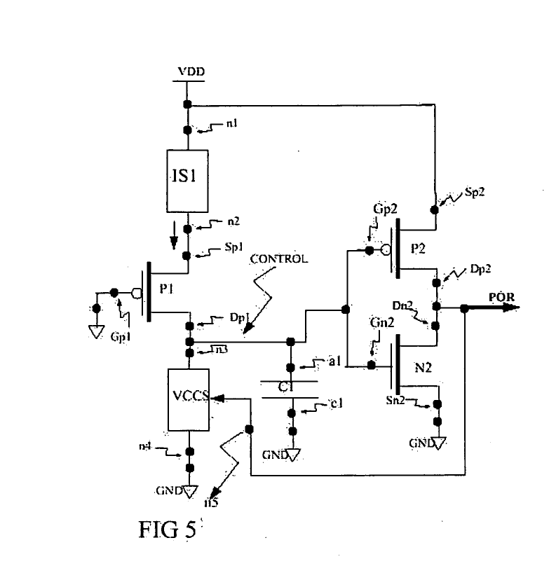

An improved Power-On Reset (POR) circuit is shown in FIG. 5. A current source IS1, whose maximum current delivering capacity is I1, has one node n1 connected to the power supply positive terminal VDD while another node n2 is connected to the source Sp1 of PMOS transistor P1. The gate Gp1 of PMOS transistor P1 is permanently connected to the power supply ground terminal while its drain Dp1 is connected to node “Control”. A Voltage Controlled Current Sink (VCCS) has one node n3 connected to node “Control”, while a second node n4 is connected to the power supply ground terminal VSS or GND while its control terminal node n5 is connected to the output terminal POR.

PMOS transistor P2 has its gate Gp2 connected to the “Control” node, while its source Sp2 is connected to the power supply terminal VDD and its drain Dp2 is connected to the output terminal POR. NMOS transistor N2 has its gate Gn2 connected to the “Control” node and its source Sn2 connected to the power supply ground terminal GND, while its drain Dn2 is connected to the output terminal POR. Input capacitor C1 has one terminal a1 connected to the “Control” node while its other terminal c1 is connected to the power supply ground terminal VSS or GND.

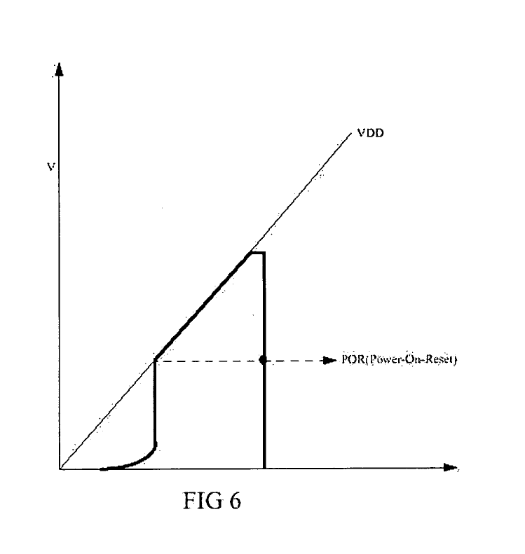

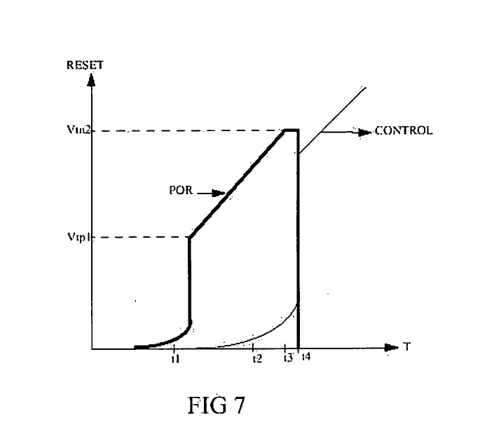

The operation of the instant circuit is described with reference to FIGS. 6 and 7. When the power supply VDD is switched on at a time t1, the “Control” node is at logic zero since the voltage control terminal of VCCS, which is connected to output POR, is not sufficient to start the VCCS. PMOS transistor P1 now acts as an isolator between node n3 of the VCCS and node n2 of current source IS1 and thereby ensures that node n3 is in a high impedance state. Capacitor C1 further ensures that any noise pick-up does not disturb the zero logic level at the “Control” node. Additional safeguards against noise pick-up can be provided by shielding or guarding this net in the circuit layout design.

PMOS transistor P2 turns on at time t1 when its Vgs is equal to its threshold voltage. The output node POR will now follow VDD as it continues to increase. The output node POR also controls the current provided by the VCCS which sinks current provided by IS1. At time t2, when the VCCS has started sinking current, switch P1 closes and node n2 connects to node n3. At time t3, the current sinking capability of the VCCS is less than the current delivering capacity of the current from IS1 causing the voltage at the “Control” node to rise as the difference current charges the “Control” node.

At time t4, when the node “Control” has charged to a level which is equal to the threshold of NMOS transistor N2, transistor N2 turns on and pulls down the output node POR to VSS. This action is reinforced by node n5 of VCCS also pulling low, resulting in very low current in VCCS. Node n3 now charges up rapidly, thereby accelerating N2 turn on and pulling down the output POR to VSS. At this time, node n5 of the VCCS is pulled down to VSS, which disables it and blocks the current drawn from the power supply, resulting in a power-down condition. Capacitor C1 acts to delay the rise time of the “Control” node, thereby making the operation unaffected by the rate of rise of the power supply voltage.

It will be apparent to those of ordinary skill in the art that the foregoing is merely illustrative and not intended to be exhaustive or limiting, having been presented by way of example only and that various modifications can be made within the scope of the above invention. Accordingly, this invention is not to be considered limited to the specific examples chosen for purposes of disclosure but rather to cover all changes and modifications, which do not constitute departures from the permissible scope of the present invention. The invention is therefore not limited by the description contained herein or by the drawings, but only by the claims.

1. An improved Power-On Reset (POR) circuit providing enhanced reliability and automatic power-down capability, comprising:
a supply voltage sensing circuit;
a delay element connected to the output of the supply voltage sensing circuit; and
a controlled switch activating an output POR signal when an output of the delay element indicates supply voltage is reduced and deactivating the output POR signal and providing controlled feedback to reduce current through the supply voltage sensing circuit when the delay element indicates the supply voltage is normal.

2. The POR circuit of claim 1, wherein the supply voltage sensing circuit comprises a constant current source connected to a current sink whose output is controlled by the controlled feedback based on the output POR signal.

3. The POR circuit of claim 2, wherein the delay element comprises a capacitor charged by a current difference between the constant current source and the current sink.

4. The POR circuit of claim 2, wherein the controlled switch disables the current sink when the supply voltage is normal.

5. The POR circuit of claim 2, wherein the constant current source is connected to the current sink through an isolating switch.

6. A power-on reset circuit, comprising:
means for supplying power;
means for outputting a power-on reset (POR) signal;
means for sensing a level of the supplied power; and
means for controlling transmission of and a value of the POR signal based on the sensed level of the supplied power, whereby the power-on reset circuit switches to a power down condition when the POR signal is terminated.

7. The circuit of claim 6, wherein the transmission controlling means comprises a switch configured to activate the POR signal when the level of the supplied power is below a threshold level and configured to deactivate the POR signal when the level of the supplied power is at least about the threshold level.

8. The circuit of claim 7, wherein the value of the POR signal is about equal to the level of the supplied power.

9. The circuit of claim 7, wherein the sensing means comprises a constant current source connected to a current sink whose output is controlled by a feedback provided by the transmission controlling means based on the level of the POR signal.

10. The circuit of claim 9, further comprising a delay element connected between the sensing means and the transmission controlling means, the delay element comprising a capacitor charged by a current difference between the constant current source and the current sink.

11. A power-on reset circuit, comprising:
a control node;
a power-on reset (POR) terminal node from which a POR signal is output based on a power supply level;
a current source having a first node for connection to a power supply and a second node;
a first transistor connected to the second node of the current source having a gate for connection to a power supply ground and a drain connected to the control node;
a voltage-controlled current sink (VCCS) having a first node connected to the control node, a second node for connection to the power supply ground, and a control terminal node connected to the POR terminal node;
a second transistor comprising a gate connected to the control node, a source node for connection to the power supply, and a drain connected to the POR terminal node; and
a third transistor comprising a gate connected to the control node, a source node for connection to the power supply ground, and a drain connected to the POR terminal node.

12. The circuit of claim 11, further comprising an input capacitor having a first terminal connected to the control node and a second terminal for connection to the power supply ground.

13. The circuit of claim 11, wherein the first transistor is a PMOS transistor, the second transistor is a PMOS transistor, and the third transistor is an NMOS transistor.
